(19) United States
(12) Patent Application Publication
(10) Pub. No.: US 2013/0258623 A1
(43) Pub. Date: Oct. 3, 2013

(54) PACKAGE STRUCTURE HAVING EMBEDDED ELECTRONIC ELEMENT AND FABRICATION METHOD THEREOF

(71) Applicant: Zhao-Chong Zeng, Taoyuan (TW)

(72) Inventor: Zhao-Chong Zeng, Taoyuan (TW)

(73) Assignee: UNIMICRON TECHNOLOGY CORPORATION, Taoyuan (TW)

(21) Appl. No.: 13/433,724

(22) Filed: Mar. 29, 2012

(51) Int. Cl. H05K 1/18; H05K 3/46; H05K 3/34

(52) U.S. Cl. 361/763; 361/761; 29/840

(57) ABSTRACT

A package structure having an embedded electronic element includes: a substrate having two opposite surfaces and a cavity penetrating the two opposite surfaces; at least a metal layer disposed on the sidewall of the cavity and extending to the surfaces of the substrate; an electronic element disposed in the cavity and having a plurality of electrode pads disposed on side surfaces thereof; and a solder material electrically connecting the electrode pads of the electronic element and the metal layer, thereby effectively alleviating the problems of alignment difficulty and high fabrication cost as encountered in the prior art.

### BACKGROUND OF THE INVENTION

1. Field of the Invention

The present invention relates to package structures and fabrication methods thereof, and more particularly, to a package structure having an embedded electronic element and a fabrication method thereof.

2. Description of Related Art

Along with the progress of semiconductor packaging technologies, various package types have been developed for semiconductor devices in addition to the conventional wire bonding and flip chip semiconductor packages. For example, an electronic element can be embedded in and electrically connected to a packaging substrate so as to form a package structure having an embedded electronic element. The electronic element can be an active component, such as a semiconductor chip, or a passive component, such as a resistor, a capacitor or an inductor. Since such a package structure has reduced size and improved electrical performance, it has become a main package trend.

FIG. 1 is a schematic cross-sectional view showing a conventional package structure having an embedded electronic element. Referring to FIG. 1, a multi-layer ceramic capacitor (MLCC) 11 is embedded in a cavity 100 of a packaging substrate 10. The multi-layer ceramic capacitor 11 has two opposite surfaces 110 and a plurality of electrode pads 111 disposed on the surfaces 110 and exposed from the cavity 100. Furthermore, a plurality of conductive vias 12 are formed by such as laser drilling for electrically connecting to the electrode pads 111.

However, since the positions of multi-layer ceramic capacitors in the cavities of a package structure cannot be set exactly the same, it is difficult to align via holes with the electrode pads of the capacitors, thereby easily resulting in electrical connection failure between subsequently formed conductive vias and the electrode pads of the capacitors. In addition, in order to enhance the bonding effect between the electrode pads that are usually made of nickel and the conductive vias, an electroplating process needs to be performed so as to form a copper layer on the electrode pads, which however increases the overall fabrication cost.

Therefore, there is a need to provide a package structure having an embedded electronic element and a fabrication method thereof so as to provide a reliable electrical connection between the package structure and the embedded electronic element and avoid additional electroplating cost.

### SUMMARY OF THE INVENTION

In view of the above-described drawbacks, the present invention provides a package structure having an embedded electronic element, which comprises: a substrate having two opposite surfaces and a cavity penetrating the two opposite surfaces; at least a metal layer formed on sidewalls of the cavity and extending to the surfaces of the substrate; an electronic element disposed in the cavity and having a plurality of electrode pads disposed on side surfaces thereof; and a solder material electrically connecting the electrode pads of the electronic element and the metal layer.

The present invention further provides a fabrication method of a package structure having an embedded electronic element, which comprises the steps of: providing a substrate having a cavity penetrating two opposite surfaces thereof; forming a metal layer on the sidewall of the cavity, wherein the metal layer extends to the surfaces of the substrate; and disposing an electronic element in the cavity of the substrate, wherein the electronic element has a plurality of electrode pads disposed on side surfaces thereof and the electrode pads are electrically connected to the metal layer through a solder material disposed between the electronic pads and the metal layer.

Through the solder material between the electronic element and the cavity, the electronic element is electrically connected to the metal layer that is formed on the sidewalls of the cavity and extends to the surfaces of the substrate. As such, conductive vias to be subsequently formed later only need to be aligned with the metal layer instead of the electrode pads of the electronic element. Therefore, the positions of the conductive vias will not be adversely affected by the embedding position of the electronic element and the alignment difficulty as encountered in the prior art is thus overcome. Furthermore, since the electrode pads are electrically connected to the metal layer through the solder material, the material of the electrode pads is not limited to copper. Consequently, the present invention dispenses with the additional copper electroplating process as in the prior art so as to reduce the overall fabrication cost.

### BRIEF DESCRIPTION OF DRAWINGS

FIG. 1 is a schematic cross-sectional view showing a conventional package structure having an embedded electronic element; and

FIGS. 2A to 2I are schematic cross-sectional views showing a package structure having an embedded electronic element and a fabrication method thereof.

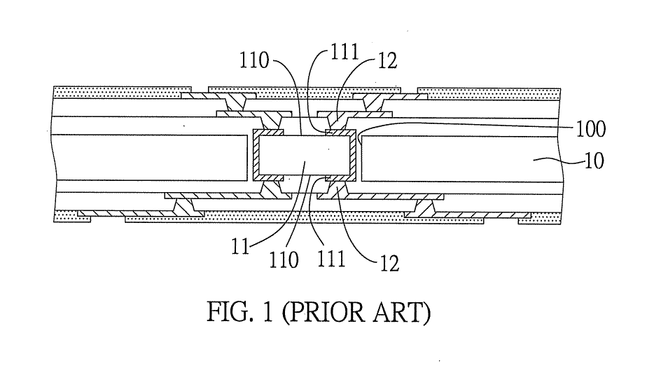

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that the drawings are only for illustrative purposes and not intended to limit the present invention. Meanwhile, terms such as ‘up’, ‘side’, ‘a’ etc. are only used as a matter of descriptive convenience and not intended to have any other significance or provide limitations for the present invention.

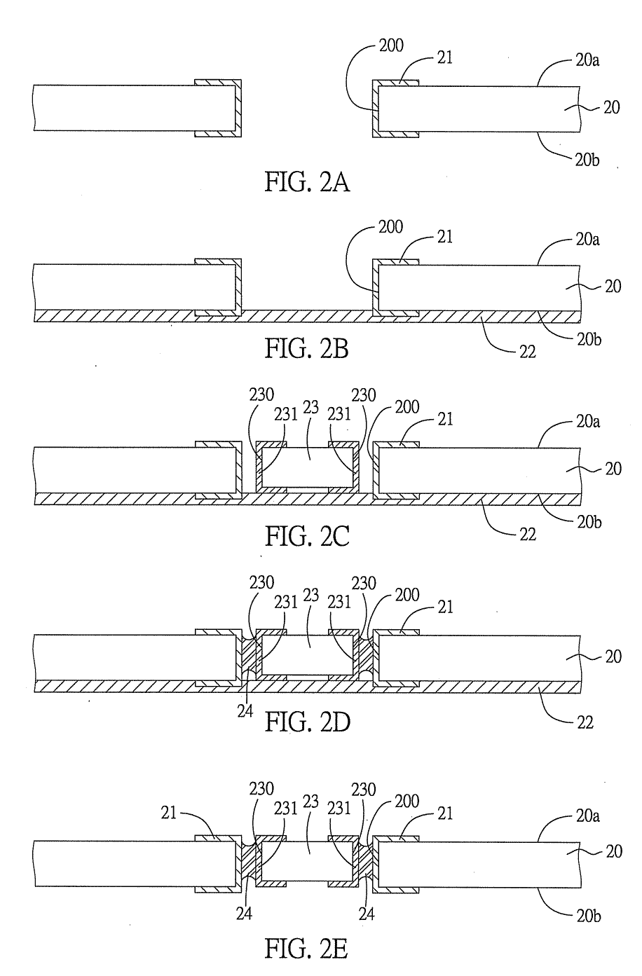

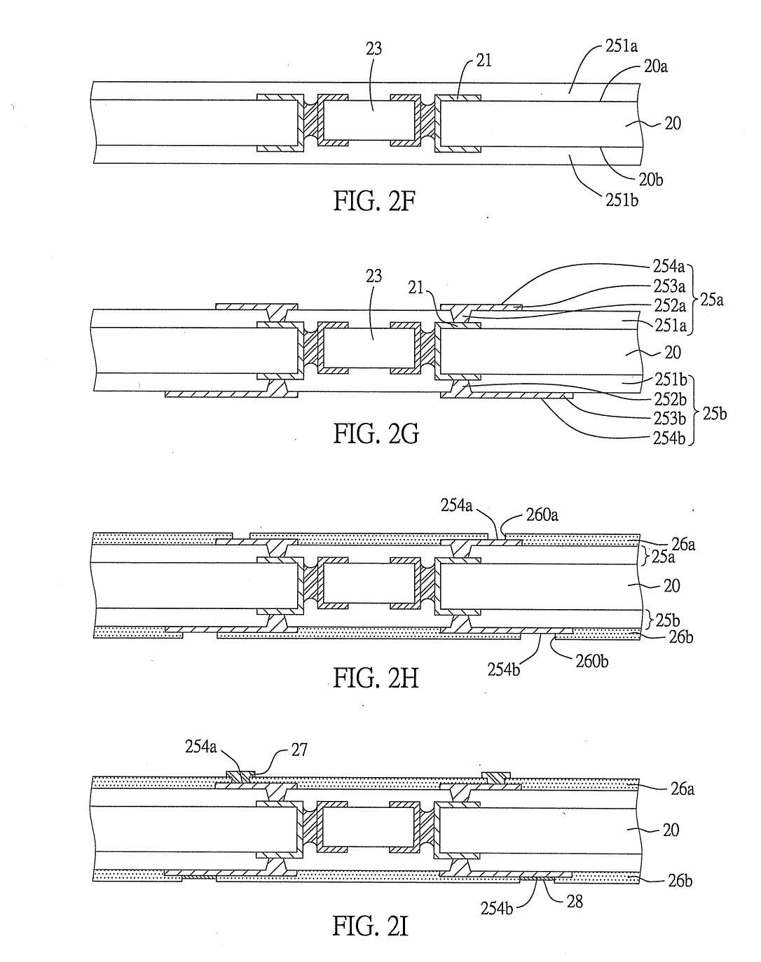

FIGS. 2A to 2I are schematic cross-sectional views showing a package structure having an embedded electronic element and a fabrication method thereof according to the present invention.

Referring to FIG. 2A, a substrate 20 having two opposite surfaces 20a, 20b and a cavity 200 penetrating through the opposite surfaces 20a, 20b is provided. A metal layer 21 is formed on the sidewalls of the cavity 200 and extends to the surfaces 20a, 20b of the substrate 20.

Referring to FIG. 2B, a carrier 22 is mounted on the surface 20b of the substrate 20 so as to cover one end of the cavity 200. The carrier 22 can be an adhesive or magnetic film.

Referring to FIG. 2C, an electronic element 23 is disposed in the cavity 200 and on the carrier 22. The electronic element 23 has a plurality of electrode pads 231 disposed on side surfaces 230 thereof. The electronic element 23 can be a multi-layer ceramic capacitor and the electrode pads 231 can be made of copper, nickel, tin or any other metal combinable with tin for a reflow process.

Referring to FIG. 2D, a solder material 24 is formed between the electrode pads 231 of the electronic element 23 and the metal layer 21 so as to electrically connect the electrode pads 231 of the electronic element 23 and the metal layer 21. The solder material 24 can be a printed solder paste or solder balls.

Referring to FIG. 2E, the carrier 22 is removed.

Referring to FIGS. 2F and 20, built-up structures 25a, 25b are formed on the surfaces 20a, 20b of the substrate 20 and the electronic element 23 and electrically connected to the metal layer 21. Each of the built-up structures 25a, 25b has at least a dielectric layer 251a, 251b, a circuit layer 253a, 253b formed on the dielectric layer 251a, 251b, and a plurality of conductive vias 252a, 252b formed in the dielectric layer 251a, 251b and electrically connecting the circuit layer 253a, 253b and the metal layer 21. Further, the outermost circuit layer 253a, 253b of the built-up structure 25a, 25b has a plurality of conductive pads 254a, 254b.

Referring to FIG. 2H, an insulating protective layer 26a, 26b is formed on the outermost layer of the built-up structure 25a, 25b, and a plurality of openings 260a, 260b are formed in the insulating protective layer 26a, 26b for exposing the conductive pads 254a, 254b.

Referring to FIG. 2I, a plurality of solder bumps 27, an OSP (Organic Solderability Preservative) layer 28 or a Ni/Au layer (not shown) is further formed on the conductive pads 254a, 254b. But it should be noted that the present invention is not limited thereto.

The present invention further provides a package structure having an embedded electronic element, which has: a substrate 20 having opposite surfaces 20a, 20b and a cavity 200 penetrating through the surfaces 20a, 20b; at least a metal layer 21 formed on the sidewalls of the cavity 200 and extending to the surfaces 20a, 20b of the substrate 20a; an electronic element 23 disposed in the cavity 200 and having a plurality of electrode pads 231 disposed on side surfaces 230 thereof; and a solder material 24 disposed between the electrode pads 231 and the metal layer 21 so as to electrically connect the electronic element 23 and the metal layer 21.

The above-described package structure further has built-up structures 25a, 25b formed on the surfaces 20a, 20b of the substrate 20 and the electronic element 23 and electrically connected to the metal layer 21.

In the above-described package structure, each of the built-up structures 25a, 25b have at least a dielectric layer 251a, 251b, a circuit layer 253a, 253b formed on the dielectric layer 251a, 251b and a plurality of conductive vias 252a, 252b formed in the dielectric layer 251a, 251b for electrically connecting the circuit layer 253a, 253b and the metal layer 21. Further, the outermost circuit layer 253a, 253b of the built-up structure 25a, 25b has a plurality of conductive pads 254a, 254b.

The above-described package structure further has an insulating protective layer 26a, 26b formed on the outermost layer of the built-up structure 25a, 25b and having a plurality of openings 260a, 260b therein for exposing the conductive pads 254a, 254b.

The above-described package structure further has a plurality of solder bumps 27, an OSP layer 28 or a Ni/Au layer disposed on the conductive pads 254a, 254b.

In the above-described package structure, the electronic element 23 can be a multi-layer ceramic capacitor, the electrode pads 231 can be made of copper, nickel or tin, and the solder material 24 can be a solder paste or a solder ball.

According to the present invention, through the solder material between the electronic element and the cavity, the electronic element is electrically connected to the metal layer that is disposed on the sidewall of the cavity and extends to the surfaces of the substrate. As such, conductive vias to be formed later only need to be aligned with the metal layer instead of the electrode pads of the electronic element. Therefore, the positions of the conductive vias will not be adversely affected by the embedding position of the electronic element and the alignment difficulty as encountered in the prior art is overcome. Furthermore, since the electrode pads are electrically connected to the metal layer through the solder material, the material of the electrode pads is not limited to copper. Consequently, the present invention dispenses with the additional copper electroplating process as in the prior art so as to reduce the overall fabrication cost.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A package structure having an embedded electronic element, comprising:
a substrate having two opposite surfaces and a cavity penetrating the two opposite surfaces;
at least a metal layer formed on sidewalls of the cavity and extending to the surfaces of the substrate;
an electronic element disposed in the cavity and having a plurality of electrode pads disposed on side surfaces thereof; and
a solder material electrically connecting the electrode pads of the electronic element and the metal layer.

2. The structure of claim 1, further comprising built-up structures formed on the surfaces of the substrate and the electronic element and electrically connected to the metal layer.

3. The structure of claim 2, wherein each of the built-up structures comprises at least a dielectric layer, a circuit layer formed on the dielectric layer, and a plurality of conductive vias formed in the dielectric layer for electrically connecting the circuit layer and the metal layer, the outermost circuit layer of each of the built-up structures, having a plurality of conductive pads.

4. The structure of claim 3, further comprising an insulating protective layer formed on the outermost layer of each of the built-up structures and having a plurality of openings formed therein for exposing the conductive pads, respectively.

5. The structure of claim 3, further comprising a plurality of solder bumps, an organic solderability preservative (OSP) layer or a Ni/Au layer formed on the conductive pads.

6. The structure of claim 1, wherein the electronic element is a multi-layer ceramic capacitor.

7. The structure of claim 1, wherein the electrode pads of the electronic element are made of copper, nickel or tin.

8. The structure of claim 1, wherein the solder material is a solder paste or solder balls.

9. A fabrication method of a package structure having an embedded electronic element, comprising the steps of:
providing a substrate having a cavity penetrating two opposite surfaces thereof;
forming a metal layer on sidewalls of the cavity, wherein the metal layer extends to the surfaces of the substrate; and
disposing an electronic element in the cavity of the substrate, wherein the electronic element has a plurality of electrode pads disposed on side surfaces thereof and the electrode pads are electrically connected to the metal layer through a solder material disposed between the electronic pads and the metal layer.

10. The method of claim 9, wherein disposing the electronic element in the cavity comprises the steps of:
mounting a carrier on one of the surfaces of the substrate so as to cover one end of the cavity;
disposing the electronic element on the carrier via the cavity;
forming the solder material between the electrode pads of the electronic element and the metal layer; and
removing the carrier.

11. The method of claim 9, further comprising forming built-up structures on the surfaces of the substrate and the electronic element, the built-up structures electrically connecting the metal layer.

12. The method of claim 11, wherein each of the built-up structures comprises at least a dielectric layer, a circuit layer formed on the dielectric layer and a plurality of conductive vias formed in the dielectric layer for electrically connecting the circuit layer and the metal layer, the outermost circuit layer of the built-up structure having a plurality of conductive pads.

13. The method of claim 12, further comprising forming an insulating protective layer on the outermost layer of each of the built-up structures and forming a plurality of openings in the insulating protective layer for exposing the conductive pads, respectively.

14. The method of claim 12, further comprising forming a plurality of solder bumps, an OSP layer or a Ni/Au layer on the conductive pads.

15. The method of claim 9, wherein the electronic element is a multi-layer ceramic capacitor.

16. The method of claim 9, wherein the electrode pads of the electronic element are made of copper, nickel or tin.

17. The method of claim 9, wherein the solder material is a solder paste or solder balls.

18. The method of claim 10, wherein the carrier is an adhesive or magnetic film.
